(19) United States
(12) Patent Application Publication
(10) Pub. No.: US 2025/0143089 A1
(43) Pub. Date: May 1, 2025

(54) OVERHANG PATTERN FOR ADVANCED OLED PATTERNING

(71) Applicant: Applied Materials, Inc., Santa Clara, CA (US)

(72) Inventors: Yu-Hsin LIN, Zhubei City (TW); Takashi ANJIKI, Aschaffenburg, Bayern (DE); Chung-chia CHEN, Hsinchu City (TW); Jae Wook JEONG, Santa Clara, CA (US); Ji Young CHOUNG, Hwaseong-si (KR); Jungmin LEE, Santa Clara, CA (US)

(21) Appl. No.: 18/690,574

(22) PCT Filed: Dec. 13, 2023
(86) PCT No.: PCT/US2023/083899

§ 371 Date: Mar. 8, 2024

Related U.S. Application Data
(60) Provisional application No. 63/432,292, filed on Dec. 13, 2022.

(51) Int. Cl. H10K 59/122; H10K 59/12; H10K 59/80; H10K 102/00

(52) U.S. Cl. CPC H10K 59/122; H10K 59/1201; H10K 59/80515; H10K 59/80521; H10K 2102/351

(57) ABSTRACT

Embodiments described herein relate to a device. The device includes a substrate, overhang structures disposed over the substrate, and a plurality of sub-pixels. Each overhang structure has a second structure disposed over a first structure. The second structure has an overhang extension extending laterally past the first structure. The first structure includes a first sidewall opposing a second sidewall. The first sidewall and the second sidewall are connected to each other. The plurality of sub-pixels each include an organic light-emitting diode (OLED) material, and a cathode disposed over the OLED material. The cathode extends under the overhang extension such that the cathode contacts the first sidewall and the second sidewall of the first structure under the overhang extension.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

In one embodiment, a device is disclosed. The device includes a substrate, overhang structures disposed over the substrate, and a plurality of sub-pixels. Each overhang structure has a second structure disposed over a first structure. The second structure has an overhang extension extending laterally past the first structure. The first structure includes a first sidewall opposing a second sidewall. The first sidewall and the second sidewall are connected to each other. The plurality of sub-pixels each include an organic light-emitting diode (OLED) material, and a cathode disposed over the OLED material. The cathode extends under the overhang extension such that the cathode contacts the first sidewall and the second sidewall of the first structure under the overhang extension.

In another embodiment, a device is disclosed. The device includes a substrate, overhang structures disposed over the substrate, and a plurality of sub-pixels. Each overhang structure includes an second structure disposed over a first structure. The second structure includes an overhang extension extending laterally past the first structure. The first structure includes a first sidewall opposing a second sidewall and at least four angled sidewalls. An at least two of the four angled sidewalls connect a first end of the first sidewall to the first end of the second sidewall. An at least two more of the four angled sidewalls connect a second end of the first sidewall and a second end of the second sidewall. The plurality of sub-pixels include an organic light-emitting diode (OLED) material and a cathode disposed over the OLED material. The cathode extends under the overhang extension such that the cathode contacts the first sidewall, the second sidewall, and the at least four angled sidewalls of the first structure under the overhang extension. A cathode thickness at a midpoint between a cathode endpoint and an OLED endpoint on the first sidewall and the second sidewall is greater than the cathode thickness on the at least four angled sidewalls.

In yet another embodiment, method of forming a device is disclosed. The method includes depositing an OLED material at a first angle and depositing a cathode at a second angle such that the cathode contacts the first sidewall, the second sidewall, the at least two sidewalls, and the at least two more sidewalls of the first structure under the overhang extension. The overhangs are disposed over a substrate, each overhang structure having an second structure disposed over a first structure, the second structure having an overhang extension extending laterally past the first structure. The first structure includes a first sidewall opposing a second sidewall and at least two sidewalls connecting a first end of the first sidewall to a first end of the second sidewall. At least two more sidewalls connect a second end of the first sidewall to the second end of the second sidewall.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit according to embodiments.

FIG. 1B is a schematic, cross-sectional view of an overhang structure of a sub-pixel circuit according embodiments.

FIG. 1C is a schematic, cross-sectional view of a sub-pixel circuit according to embodiments.

FIG. 1D is a schematic, cross-sectional view of an overhang structure of a sub-pixel circuit according embodiments.

FIG. 2 is a schematic, top plan view of a sub-pixel circuit having a dot-type architecture, according to embodiments.

FIG. 3A is a cross-sectional view of the sub-pixel circuit at section line A-A, according to embodiments.

FIG. 3B is a cross-sectional view of the sub-pixel circuit at section line B-B, according to embodiments.

FIG. 3C is a cross-sectional view of the sub-pixel circuit at section line C-C, according to embodiments.

FIG. 3D is a cross-sectional view of the sub-pixel circuit at section line D-D, according to embodiments.

FIG. 4A is a cross-sectional view of the sub-pixel circuit at section line A-A, according to embodiments.

FIG. 4B is a cross-sectional view of the sub-pixel circuit at section line B-B, according to embodiments.

FIG. 4C is a cross-sectional view of the sub-pixel circuit at section line C-C, according to embodiments.

FIG. 4D is a cross-sectional view of the sub-pixel circuit at section line D-D, according to embodiments.

FIG. 4E is a cross-sectional view of the sub-pixel circuit at section line E-E, according to embodiments.

FIG. 5 illustrates a method of forming a sub-pixel circuit, according to embodiments.

FIGS. 6A-6C are schematic, cross-sectional views of a substrate during the method for forming the sub-pixel circuit, according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

Each of the embodiments described herein of the sub-pixel circuit include a plurality of sub-pixels with each of the sub-pixels defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more sub-pixels. Each sub-pixel has OLED materials configured to emit a white, red, green, blue or other color light when energized. E.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least an second structure disposed over a first structure. The adjacent overhang structures defining each sub-pixel of the sub-pixel circuit of the display provide for formation of the sub-pixel circuit using deposition techniques, such as evaporation deposition, and provide for the overhang structures to remain in place after the sub-pixel circuit is formed. Evaporation deposition may be utilized for deposition of OLED materials (including a hole injection layer (HIL), a hole transport layer (HTL), an emissive layer (EML), and an electron transport layer (ETL)), and cathode. In one embodiment, the HIL layer has a greater conductivity than the HTL layer. In another embodiment, the HIL layer has a greater energy level than the HTL layer. In some instances, an encapsulation layer may be disposed via evaporation deposition. In embodiments including one or more capping layers, the capping layers are disposed between the cathode and the encapsulation layer. The overhang structures and the deposition angle set by the deposition source provide for a shadowing effect during deposition with the deposition angle set by the deposition source. In order to deposit at a particular angle, the deposition source is configured to emit the deposition material at a particular angle with regard to the overhang structure. The encapsulation layer of a respective sub-pixel is disposed over the cathode with the encapsulation layer extending under at least a portion of each of the adjacent overhang structures and along a sidewall of each of the adjacent overhang structures.

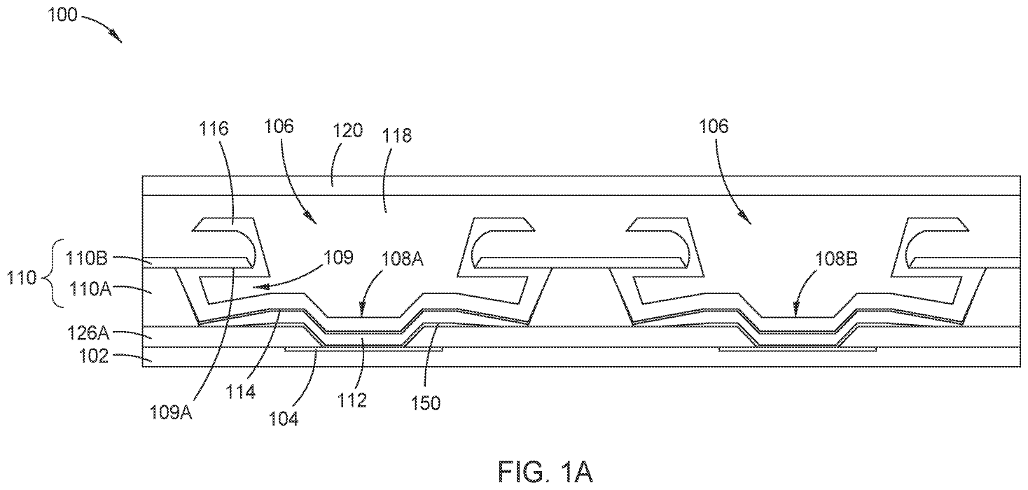

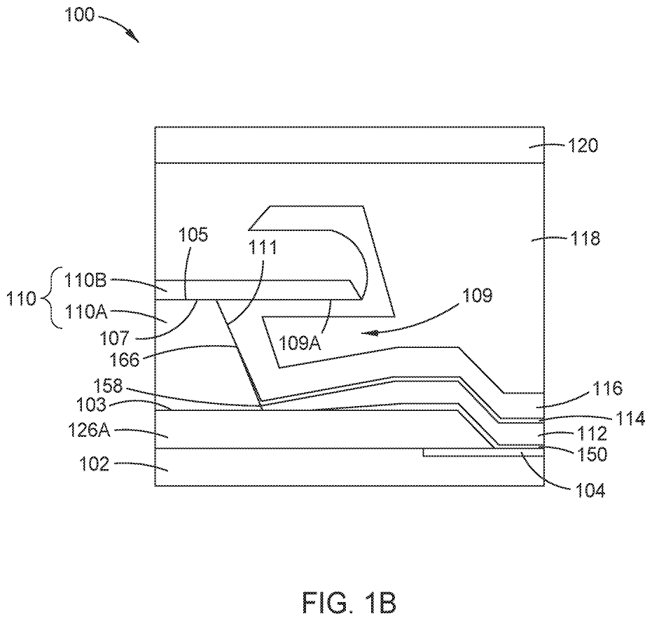

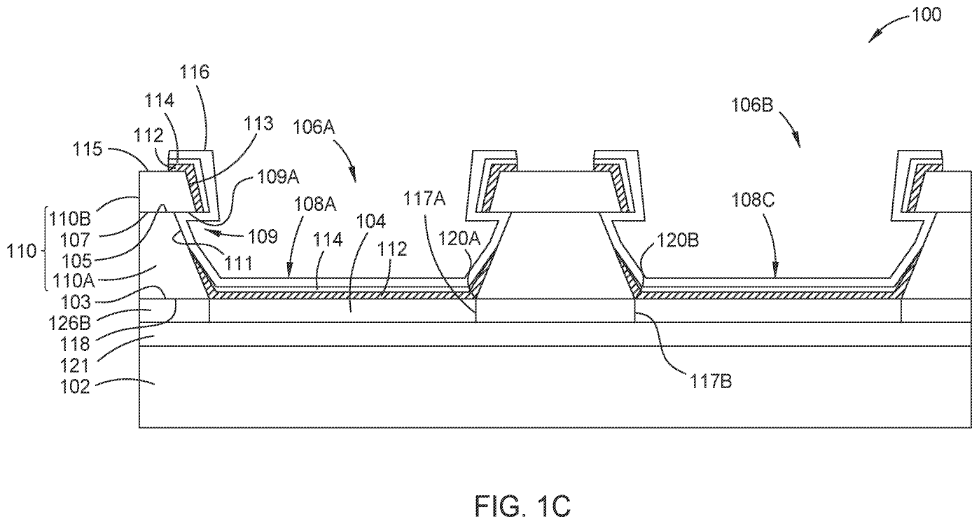

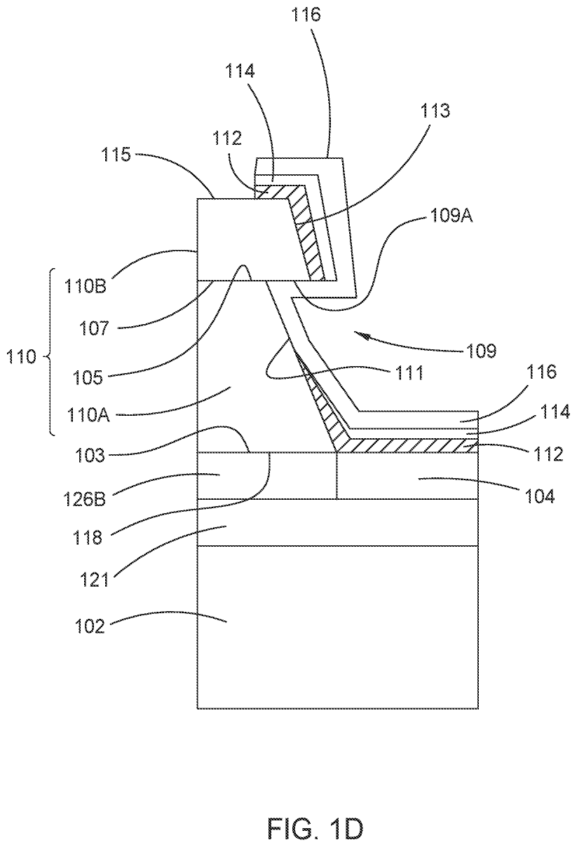

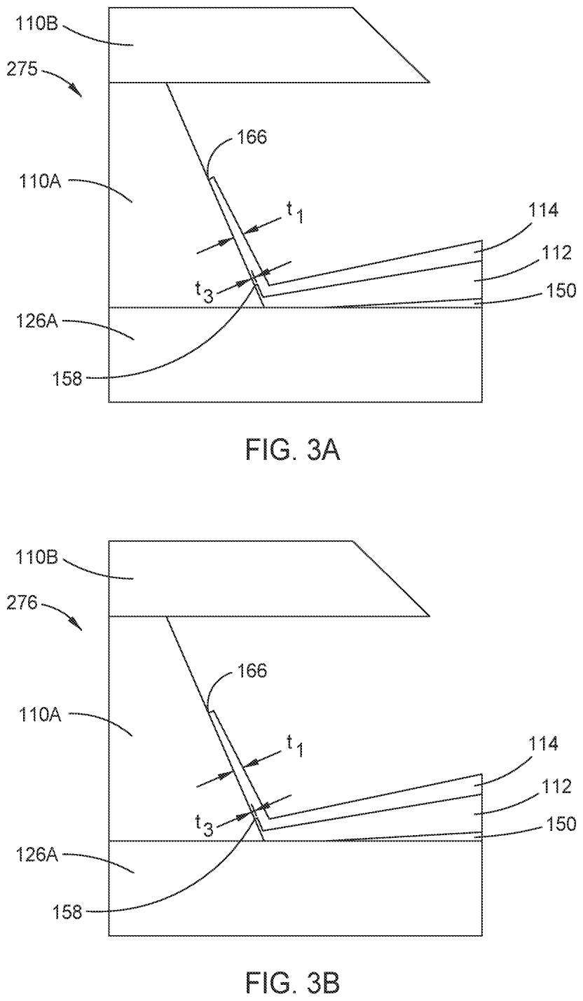

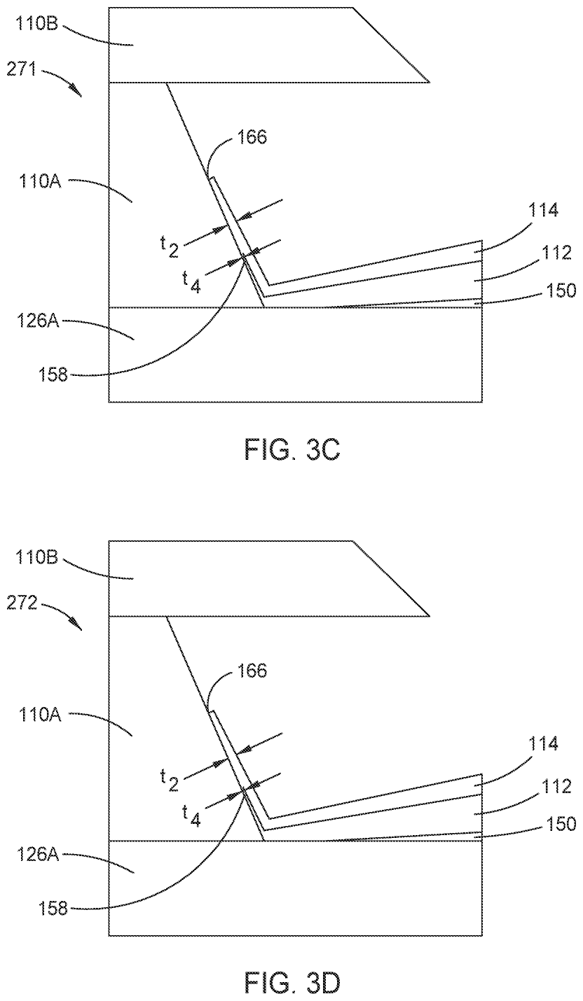

FIG. 1A is a schematic, cross-sectional view of a first sub-pixel circuit 100A according to embodiments. FIG. 1A corresponds to a cross-section of the first sub-pixel circuit 100A. FIG. 1B is a schematic, cross-sectional view of an overhang structure 110 of the first sub-pixel circuit 100A according to embodiments. FIG. 1B is shown in further detail in FIG. 3A. The first sub-pixel circuit 100A includes a substrate 102. Metal-containing layers 104 may be patterned on the substrate 102 and are defined by adjacent pixel-defining layer (PDL) structures 126A disposed over the substrate 102. In one embodiment, the PDL structures 126A are disposed on the substrate 102. In one embodiment, the metal-containing layers 104 are pre-patterned on the substrate 102. E.g., the substrate 102 is pre-patterned with metal-containing layers 104 of indium tin oxide (ITO). The metal-containing layers 104 are configured to operate as anodes of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layers 104 include, but are not limited to, chromium, titanium, gold, silver, copper, aluminum, ITO, a combination thereof, or other suitably conductive materials.

The plurality of PDL structures 126A are disposed over the substrate 102. The PDL structures 126A include one of an organic material, an organic material with an inorganic coating disposed thereover, or an inorganic material. The organic material of the PDL structures 126A includes, but is not limited to, polyimides. The inorganic material of the PDL structures 126A includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 126A define a respective sub-pixel and expose the anode (i.e., metal-containing layer 104) of the respective first sub-pixel circuit 100A.

The first sub-pixel circuit 100A has a plurality of sub-pixels 106 including at least a first sub-pixel 108A and a second sub-pixel 108B. While the Figures depict the first sub-pixel 108A and the second sub-pixel 108B, the first sub-pixel circuit 100A of the embodiments described herein may include two or more sub-pixels 106, such as a third and a fourth sub-pixel. Each sub-pixel 106 has OLED materials configured to emit a white, red, green, blue or other color light when energized. E.g., the OLED materials of the first sub-pixel 108A emits a red light when energized, the OLED materials of the second sub-pixel 108B emits a green light when energized, the OLED materials of a third sub-pixel emits a blue light when energized, and the OLED materials of a fourth sub-pixel emits another color light when energized.

Each sub-pixel 106 includes an overhang structure 110. The overhang structures 110 are permanent to the first sub-pixel circuit 100A. The overhang structures 110 further define each sub-pixel 106 of the first sub-pixel circuit 100A. Each overhang structure 110 includes adjacent overhangs 109. The adjacent overhangs 109 are defined by an overhang extension 109A of a second structure 110B extending laterally past a first structure 110A. The second structure 110B is disposed over the first structure 110A. In one embodiment, the second structure 110B is disposed on the first structure 110A.

In one embodiment, the overhang structures 110 includes the second structure 110B of a non-conductive inorganic material and the first structure 110A of a conductive inorganic material. In another embodiment, the overhang structures 110 includes the second structure 110B of a conductive inorganic material and the first structure 110A of a conductive inorganic material. The conductive materials of the first structure 110A include aluminum (Al), aluminum neodymium (AlNd), molybdenum (Mo), molybdenum tungsten (MoW), copper (Cu), or combinations thereof. The inorganic materials of the second structure include titanium (Ti), silicon nitride (Si₃N₄), silicon oxide (SiO₂), silicon oxynitride (Si₂N₂O), or combinations thereof. In one embodiment, the first structure is a metal containing material. In one example, the metal-containing material is a transparent conductive oxide (TCO) material. The TCO material includes, but is not limited to, indium zinc oxide (IZO), indium tin oxide (ITO), indium gallium zinc oxide (IGZO), or combinations thereof. The overhang structures 110 are able to remain in place, i.e., are permanent.

In one embodiment, a HIL material 150 of the OLED materials is disposed over and in contact with the metal-containing layer 104. In one embodiment, the HIL material 150 is different from the material of the first structure 110A and the second structure 110B. An additional OLED material 112 is disposed over the HIL material 150 and extends past an endpoint of the HIL material 150. In one embodiment, the additional OLED material is disposed on the HIL material 150. In one embodiment, the additional OLED material 112 is different from the material of the first structure 110A and the second structure 110B. The overhang structures 110 and deposition angle define an OLED endpoint 158 and a cathode endpoint 166. The overhang structures 110 provide for a shadowing effect during deposition at an angle. Deposition angles are set by the deposition source. The deposition source may be an evaporation source. The additional OLED material 112 and cathode 114 are deposited via evaporation deposition.

Adjacent overhangs 109 are defined by the overhang extension 109A of the second structure 110B. At least a bottom surface 107 of the second structure 110B is wider than a upper surface 105 of the first structure 110A to form the overhang extension 109A (as shown in FIG. 1B) of the overhang 109. The second structure 110B is disposed over an upper surface 105 of the first structure 110A. The overhang extension 109A of the second structure 110B forms the overhang 109 and allows for the second structure 110B to shadow the first structure 110A. The shadowing of the overhang 109 provides for deposition of each of the HIL material 150, the additional OLED material 112, and a cathode 114. Each of the HIL material 150 and the additional OLED material 112 are disposed under the overhang 109. The cathode 114 is disposed over the additional OLED material 112 and extends under the adjacent overhang 109.

In one embodiment, the HIL material 150 is disposed over and in contact with the metal-containing layers 104 and the upper surface 103 of the PDL structure 126A. The HIL material 150 is disposed under the adjacent overhangs 109, such that the HIL material 150 contacts the first structure 110A. The additional OLED material 112 is disposed over the HIL material 150. In one embodiment, the additional OLED material is disposed on the HIL material 150. The additional OLED material extends under the adjacent overhang 109 and is disposed over a first portion of the first structure 110A.

The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A and the second structure 110B. In some embodiments, the HIL material 150, the additional OLED material 112, and the cathode 114 are disposed on the sidewall 111 of the first structure 110A.

Each sub-pixel 106 includes an encapsulation layer 116. The encapsulation layer 116 may be or may correspond to a local passivation layer. The encapsulation layer 116 of a respective sub-pixel is disposed over the cathode 114 (and additional OLED material 112) with the encapsulation layer 116 extending under at least a portion of each of the overhangs 109 and along a sidewall of each of the first structure 110A and the second structure 110B. The encapsulation layer 116 includes the non-conductive inorganic material, such as the silicon-containing material. The silicon-containing material may include Si₃N₄ containing materials.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the first sub-pixel circuit 100A further includes at least a global passivation layer 120 disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer 120.

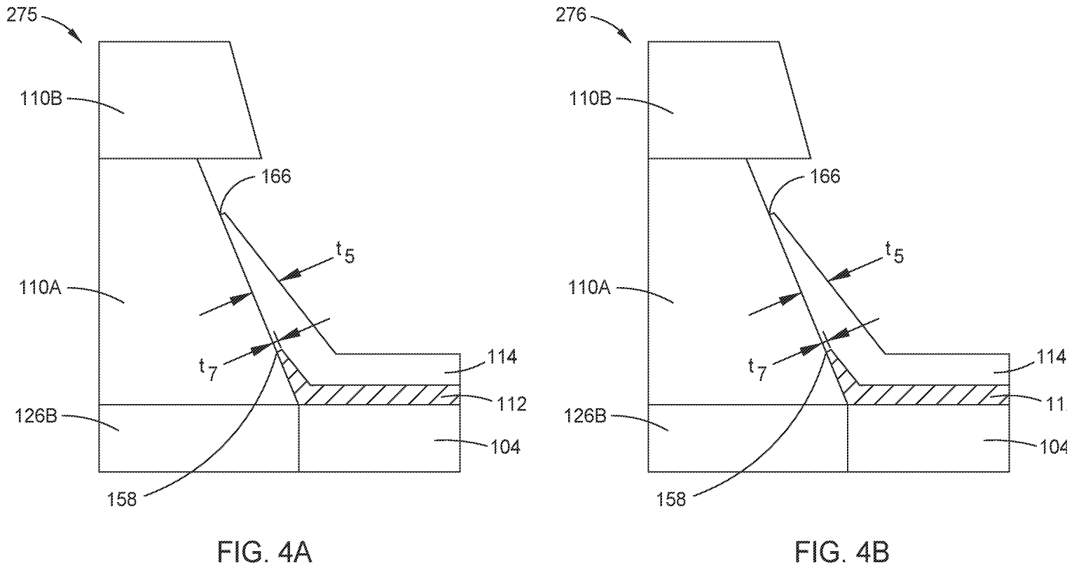

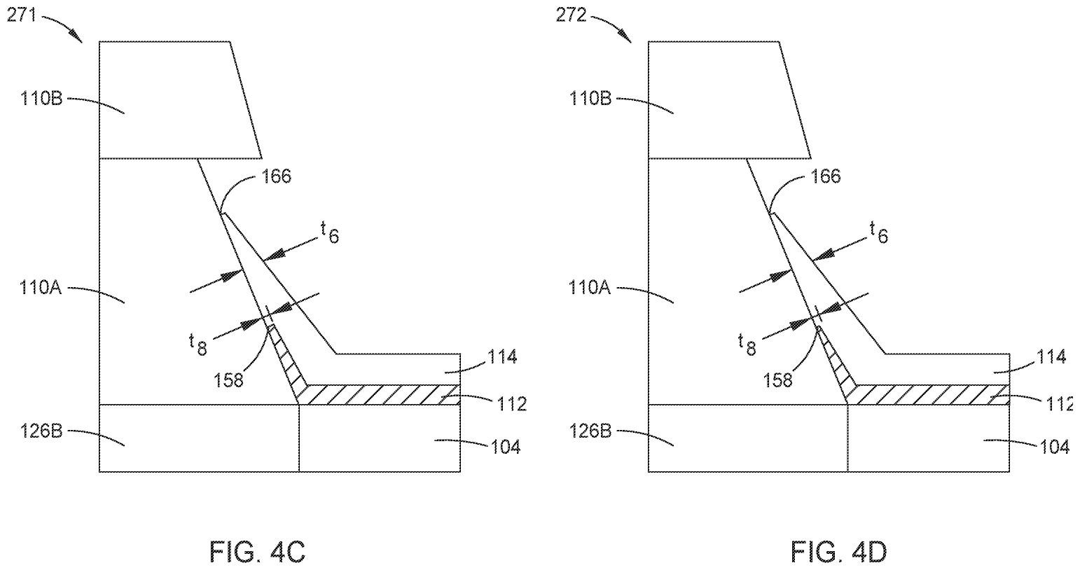

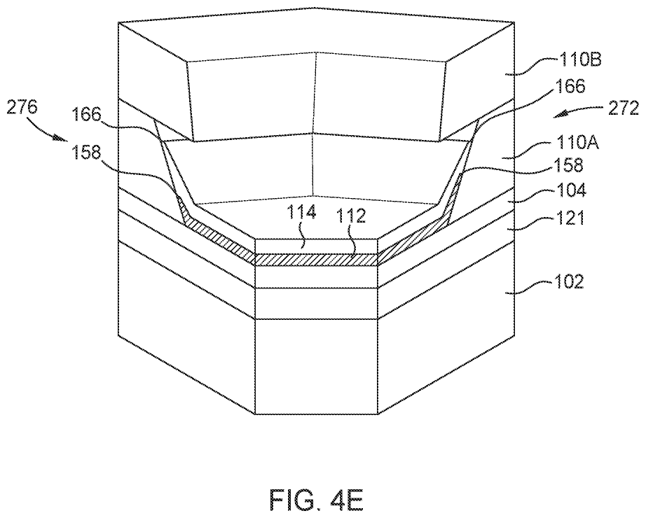

FIG. 1C is a schematic, cross-sectional view of a second sub-pixel circuit 100B according to embodiments. FIG. 1D is a schematic, cross-sectional view of the second sub-pixel circuit 100B according to embodiments. FIG. 1D is shown in further detail in FIG. 4A. The second sub-pixel circuit 100B includes a substrate 102. A base layer 121 may be patterned over the substrate 102. The base layer 121 includes, but is not limited to, a CMOS layer. Metal-containing layers 104 (e.g., anodes) may be patterned on the base layer 121 and are defined by adjacent pixel isolation structures (PIS) 126B disposed on the substrate 102. In one embodiment, the metal-containing layer 104 are pre-patterned on the base layer 121. E.g., the base layer 121 is pre-patterned with metal-containing layer 104 of indium tin oxide (ITO). The metal-containing layer 104 may be disposed on the substrate 102. The metal-containing layer 104 are configured to operate as anodes of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layer 104 include, but are not limited to, chromium, titanium, gold, silver, copper, aluminum, ITO, a combination thereof, or other suitably conductive materials.

The PIS 126B are disposed over the substrate 102. The PIS 126B may be disposed on the base layer 121. The PIS 126B include one of an organic material, an organic material with an inorganic coating disposed thereover, or an inorganic material. The organic material of the PIS 126B includes, but is not limited to, polyimides. The inorganic material of the PIS 126B includes, but is not limited to, silicon oxide (SiO₂), silicon nitride (Si₃N₄), silicon oxynitride (Si₂N₂O), magnesium fluoride (MgF₂), or combinations thereof. Adjacent PIS 126B define a respective sub-pixel and expose the metal-containing layer 104 of the respective second sub-pixel circuit 100B.

The second sub-pixel circuit 100B has a plurality of sub-pixel lines (e.g., first sub-pixel line 106A and second sub-pixel line 106B). The sub-pixel lines are adjacent to each other along the pixel plane. Each sub-pixel line includes at least two sub-pixels. E.g., the first sub-pixel line 106A includes a first sub-pixel 108A and a second sub-pixel (not shown) and the second sub-pixel line 106B includes a third sub-pixel 108C and a fourth sub-pixel (not shown). While FIG. 1A depicts the first sub-pixel line 106A and the second sub-pixel line 106B, the second sub-pixel circuit 100B of the embodiments described herein may include two or more sub-pixel lines, such as a third sub-pixel line and a fourth sub-pixel. Each sub-pixel line has OLED materials configured to emit a white, red, green, blue or other color light when energized. E.g., the OLED materials of the first sub-pixel line 106A emits a red light when energized, the OLED materials of the second sub-pixel line 106B emits a green light when energized, the OLED materials of a third sub-pixel line emits a blue light when energized, and the OLED materials of a fourth sub-pixel emits another color light when energized. The OLED materials within a pixel line may be configured to emit the same color light when energized. E.g., the OLED materials of the first sub-pixel 108A and the second sub-pixel of the first sub-pixel line 106A emit a red light when energized and the OLED materials of the third sub-pixel 108C and the fourth sub-pixel of the second sub-pixel line 106B emit a green light when energized.

Each sub-pixel line includes adjacent overhang structures 110, with adjacent sub-pixel lines sharing the adjacent overhang structures 110. The overhang structures 110 are permanent to the second sub-pixel circuit 100B. The overhang structures 110 further define each sub-pixel line of the second sub-pixel circuit 100B. Each overhang structure 110 includes adjacent overhangs 109. The adjacent overhangs 109 are defined by an overhang extension 109A of a second structure 110B extending laterally past an upper surface 105 of a first structure 110A. The first structure 110A is disposed over an upper surface 103 of the PIS 126B. A first endpoint 120A of a bottom surface 118 of the first structure 110A may extend to or past a first edge 117A of the PIS 126B. A second endpoint 120B of the bottom surface of the first structure 110A may extend to or past a second edge 117B the PIS 126B. The second structure 110B is disposed over the first structure 110A. The second structure 110B may be disposed on the upper surface 105 of the first structure 110A. The second structure 110B may also be disposed over an intermediate structure. The intermediate structure may be disposed over the upper surface 105 of the first structure 110A. The intermediate structure may be a seed layer or an adhesion layer. The seed layer functions as a current path for the second sub-pixel circuit 100B. The seed layer may include a titanium (Ti) material. The adhesion promotion layer improves adhesion between the first structure 110A and the second structure 110B. The adhesion layer may include a chromium (Cr) material.

In one embodiment, the overhang structures 110 include the second structure 110B of a conductive inorganic material and the first structure 110A of a non-conductive inorganic material. The conductive materials of the second structure 110B include a copper (Cu), chromium (Cr), aluminum (Al), aluminum neodymium (AlNd), molybdenum (Mo), molybdenum tungsten (MoW), or combinations thereof. The non-conductive materials of the first structure 110A include amorphous silicon (a-Si), titanium (Ti), silicon nitride (Si₃N₄), silicon oxide (SiO₂), silicon oxynitride (Si₂N₂O), or combinations thereof. The overhang structures 110 are able to remain in place, i.e., are permanent.

The adjacent overhangs 109 are defined by the overhang extension 109A. At least a bottom surface 107 of the second structure 110B is wider than the upper surface 105 of the first structure 110A to form the overhang extension 109A. The overhang extension 109A of the second structure 110B forms the overhang 109 and allows for the second structure 110B to shadow the first structure 110A. The shadowing of the overhang 109 provides for evaporation deposition of an OLED material 112 and a cathode 114. The OLED material 112 may include one or more of a HIL, a HTL, an EML, and an ETL. The OLED material 112 is disposed over and in contact with the metal-containing layer 104. The OLED material 112 is disposed under adjacent overhangs 109 and may contact a sidewall 111 of the first structure 110A. In one embodiment, the OLED material 112 is different from the material of the first structure 110A, the second structure 110B, and the intermediate structure. The cathode 114 is disposed over the OLED material 112 and extends under the adjacent overhangs 109. The cathode 114 extends past an endpoint of the OLED material 112. The cathode 114 contacts the sidewall 111 of the first structure 110A. The overhang structures 110 and an evaporation angle set by an evaporation source define deposition angles, i.e., the overhang structures provide for a shadowing effect during evaporation deposition with the evaporation angle set by the evaporation source.

The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A, the second structure 110B, and intermediate structure. In some embodiments, e.g., as shown in FIG. 1C as applied to the second sub-pixel circuit 100B, the OLED material 112 and the cathode 114 are disposed over a sidewall 113 of the second structure 110B of the overhang structures 110 in the pixel plane. In other embodiments, the OLED material 112 and the cathode 114 are disposed over an upper surface 115 of the second structure 110B of the overhang structures 110 in the pixel plane. In still other embodiments, the OLED material 112 and the cathode 114 end on the sidewall 111 of the first structure 110A, i.e., are not disposed over the sidewall 113 of the second structure 110B or the upper surface 115 of the second structure 110B in the pixel plane.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs 109 and along a sidewall 111 of each of the first structure 110A and the second structure 110B. The encapsulation layer 116 is disposed over the cathode 114 and extends at least to contact the cathode 114 over the sidewall 111 of the first structure 110A in the pixel plane. In some embodiments, the encapsulation layer 116 extends to contact the sidewall 111 of the first structure 110A. In the illustrated embodiments as shown in FIGS. 1C and 1D, the encapsulation layer 116 extends to contact the second structure 110B at an underside surface of the overhang extension 109A, the sidewall 113 of the second structure 110B, and the upper surface 115 of the second structure 110B. In some embodiments, the encapsulation layer 116 extends to contact the second structure 110B at an underside surface of the overhang extension 109A and to be disposed over the OLED material 112 and the cathode 114 when the OLED material 112 and the cathode 114 are disposed over the sidewall 113 and upper surface 115 of the second structure 110B. In some embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

Each sub-pixel line may adjacent separation structures, with adjacent sub-pixels sharing the adjacent separation structures in the line plane. The separation structures are permanent to the second sub-pixel circuit 100B. The separation structures further define each sub-pixel of the sub-pixel line of the second sub-pixel circuit 100B. The separation structures are disposed over an upper surface 103 of the PIS 126B.

The OLED material 112 is disposed over and in contact with the metal-containing layer 104 and the separation structure in the line plane. The cathode 114 is disposed over the OLED material 112 in the line plane. The encapsulation layer 116 is disposed over the cathode 114 in the line plane. As shown in FIG. 1D, the OLED material 112, the cathode 114, and the encapsulation layer 116 maintain continuity along the length of the line plane in order to apply current across each sub-pixel 106.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the second sub-pixel circuit 100B further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer.

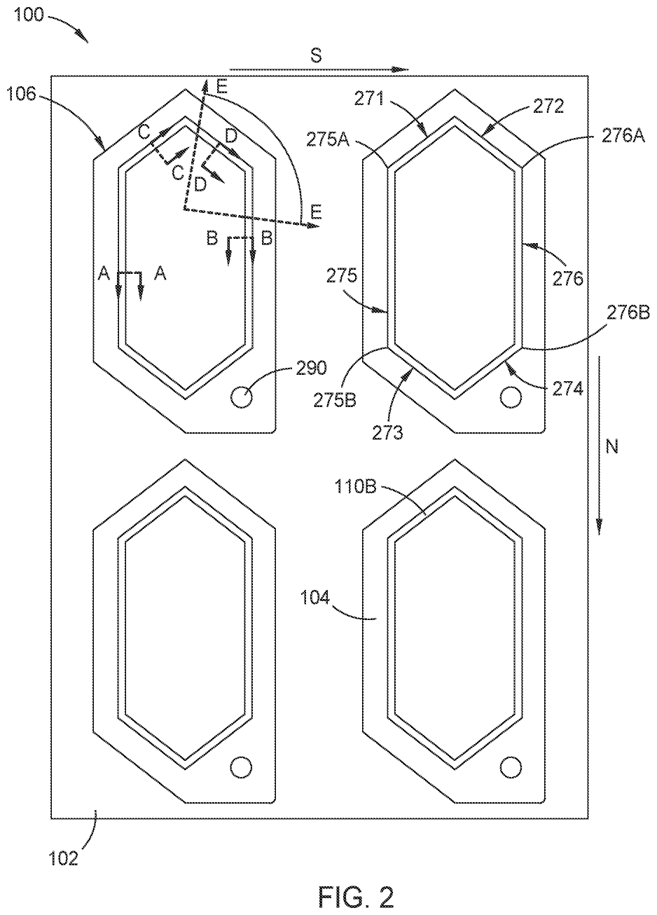

FIG. 2 is a schematic, top plan view of the first sub-pixel circuit 100A or the second sub-pixel circuit 100B having a dot-type architecture, according to embodiments. FIG. 2 shows the first sub-pixel circuit 100A or the second sub-pixel circuit 100B prior to deposition the encapsulation layer 116. The first sub-pixel circuit 100A or the second sub-pixel circuit 100B includes the plurality of adjacent PDL structures 126A disposed over the substrate 102. The overhang structures 110 are disposed over an upper surface 103 of the PDL structures 126A. Each overhang structure 110 has the second structure 110B disposed over the first structure 110A. The first structure 110A comprises a first sidewall 275 opposing a second sidewall 276 and at least two sidewalls 271, 272 connecting a first end 275A of the first sidewall 275 to the first end 276A of the second sidewall 276. In one embodiment, the first sidewall 275 and the second sidewall 276 are oriented parallel to a nozzle direction N. The nozzle direction N is perpendicular to (e.g., normal to) a scan direction S. The at least two sidewalls 271, 272 can be angled about 5 degrees to about 85 degrees from the first sidewall 275 and the second sidewall 276. The angle of the at least two sidewalls 271, 272 further define an OLED endpoint 158 and a cathode endpoint 166. The overhang structures 110 and the angle of the at least two sidewalls 271, 272 provide for a shadowing effect during deposition at an angle. The second structure 110B has an overhang extension 109A extending laterally past the first sidewall 275, the second sidewall 276, and the at least two sidewalls 271, 272 of the first structure 110A to create the overhang 109.

The first sub-pixel circuit 100A or the second sub-pixel circuit 100B further includes a plurality of sub-pixels 106. Each sub-pixel 106 includes the organic light-emitting diode (OLED) material 112 and the cathode 114 disposed over the additional OLED material 112. The cathode 114 extends under the overhang extension 109A and contacts the first sidewall 275, the second sidewall 276, and the at least two sidewalls 271, 272 of the first structure 110A under the overhang extension 109A. The cathode 114 is disposed over the first sidewall 275, the second sidewall 276, and the at least two sidewalls 271, 272 to a cathode endpoint 166. In some embodiments, the additional OLED material 112 extends under the overhang extension 109A and contacts the first sidewall 275, the second sidewall 276, and the at least two sidewalls 271, 272 of the first structure 110A under the overhang extension 109A. The additional OLED material 112 is disposed over the first sidewall 275, the second sidewall 276, and the at least two sidewalls 271, 272 to an OLED endpoint 158.

In one embodiment, the sub-pixels further include the metal-containing layers 104 and a via hole 290. In one embodiment, the via hole is disposed through the metal-containing layer 104. A conductive layer is disposed in the via hole 290 to connect the metal-containing layer 104 to a thin-film transistor (TFT) disposed below the metal-containing layer 104. The TFT provides a driving current to the plurality of sub-pixels 106. The metal-containing layers 104 may be patterned on the substrate 102 and are defined by adjacent pixel-defining layer (PDL) structures 126A disposed over the substrate 102 in the first sub-pixel circuit 100A. In one embodiment, the metal-containing layers 104 are pre-patterned on the substrate 102. E.g., the substrate 102 is pre-patterned with metal-containing layers 104 of indium tin oxide (ITO). The metal-containing layers 104 are configured to operate as anodes of respective sub-pixels.

In one embodiment, the sub-pixel 106 further includes at least two more sidewalls 273, 274 connecting a second end 275B of the first sidewall 275 to a second end 276B of the second sidewall 276. The at least two more sidewalls 273, 274 can be angled about 5 degrees to about 85 degrees from the first sidewall 275 and the second sidewall 276. The angle of the at least two more sidewalls 273, 274 further define an OLED endpoint 158 and a cathode endpoint 166. The overhang structures 110 and the angle of the at least two more sidewalls 273, 274 provide for a shadowing effect during deposition at an angle. The at least two sidewalls 271, 272 include a first portion 271 and a second portion 272 and the at least two more sidewalls include a third portion 273 and a fourth portion 274. The first portion 271 of the at least two sidewalls 271, 272 is opposite to the fourth portion 274 of the at least two more sidewalls 273, 274. The second portion 272 of the at least two sidewalls 271, 272 is opposite to the third portion 273 of the at least two more sidewalls 273, 274. In one embodiment, the first portion 271 of the at least two sidewalls 271, 272 is opposite and parallel to the fourth portion 274 of the at least two more sidewalls 273, 274 and the second portion 272 of the at least two sidewalls 271, 272 is opposite and parallel to the third portion 273 of the at least two more sidewalls 273, 274.

The cathode 114 extends under the overhang extension 109A and contacts the first sidewall 275, the second sidewall 276, the at least two sidewalls 271, 272 and the at least two more sidewalls 273, 274 of the first structure 110A under the overhang extension 109A. The cathode 114 is disposed over the first sidewall 275, the second sidewall 276, the at least two sidewalls 271, 272 and the at least two more sidewalls 273, 274 to a cathode endpoint 166. In some embodiments, the additional OLED material 112 extends under the overhang extension 109A and contacts the first sidewall 275, the second sidewall 276, the at least two sidewalls 271, 272 and the at least two more sidewalls 273, 274 of the first structure 110A under the overhang extension 109A. The additional OLED material 112 is disposed over the first sidewall 275, the second sidewall 276, the at least two sidewalls 271, 272 and the at least two more sidewalls 273, 274 to an OLED endpoint 158.

In one embodiment, the first sidewall 275, the second sidewall 276, the at least two sidewalls 271, 272, and the at least two more sidewalls 273, 274 form a hexagonal sub-pixel 106. The first end 275A of the first sidewall 275 connects to the first portion 271 of the at least two sidewalls 271, 272 and the second end 275B of the first sidewall 275 connects to the third portion 273 of the at least two more sidewalls 273, 274. The first end 276A of the second sidewall 276 connects to the second portion 272 of the at least two sidewalls 271, 272 and the second end 276B of the second sidewall 276 connects to the fourth portion 274 of the at least two more sidewalls 273, 274. The first portion 271 connects to the second portion 272. The third portion 273 connects to the fourth portion 274. In some embodiments, the corners formed by the first sidewall 275, second sidewall 276, at least two sidewalls 271, 272, and at least two more sidewalls 273, 274 have a corner radius.

FIGS. 3A-3D show cross-sectional views of the sub-pixel 106. FIG. 3A is a cross-sectional view of the first sidewall 275 of the first sub-pixel circuit 100A at section line A-A. FIG. 3B is a cross-sectional view of the second sidewall 275 of the first sub-pixel circuit 100A at section line B-B. FIG. 3C is a cross-sectional view of the first portion 271 of the at least two sidewalls 271, 272 of the first sub-pixel circuit 100A at section line C-C. FIG. 3D is a cross-sectional view of the second portion 272 of the at least two sidewalls 271, 272 of the first sub-pixel circuit 100A at section line D-D. FIG. 3A-3D show the cross-sections after the deposition of the cathode 114, the additional OLED material 112, and the HIL material 150. The first sidewall 275 of the first structure 110A and the second sidewall 276 of the first structure 110A have a cathode thickness t₁. The cathode thickness t₁ is at a midpoint between the cathode endpoint 166 and the OLED endpoint 158 of the first sidewall 275 of the first structure 110A and second sidewall 276 of the first structure 110A. A first cathode volume vi is the total volume of the cathode 114 disposed on the first sidewall 275 and second sidewall 276 from the cathode endpoint 166 to the OLED endpoint 158. The at least two sidewalls 271, 272 of the first structure 110A and at least two more sidewalls 273, 274 of the first structure 110A have a cathode thickness t₂. The cathode thickness t₂ is at a midpoint between the cathode endpoint 166 and the OLED endpoint 158 of the at least two sidewalls 271, 272 and at least two more sidewalls 273, 274. A second cathode volume v₂ is the total volume of the cathode 114 disposed on the at least two sidewalls 271,272 and at least two more sidewalls 273, 274 from the cathode endpoint 166 to the OLED endpoint 158. In one embodiment, the cathode thickness t₁ is greater than the cathode thickness t₂. In one embodiment, the cathode thickness t₂ is about 10% to about 99% of the cathode thickness t₁. In one embodiment, the first cathode volume vi of the cathode 114 on the first sidewall 275 and the second sidewall 276 is greater than the second cathode volume v₂ on the at least two sidewalls 271, 272 and the at least two more sidewalls 273, 274. The second cathode volume v₂ on the at least two sidewalls 271, 272 and the at least two more sidewalls 273, 274 is between about 10% and about 99% of the first cathode volume vi of the cathode 114 on the first sidewall 275 and the second sidewall 276. The first sidewall 275 and the second sidewall 276 have an OLED thickness t₃. The at least two sidewalls 271,272 and at least two more sidewalls 273, 274 have an OLED thickness t₄. The OLED thicknesses t₃ and t₄ are measured at the OLED endpoint 158.

The overhang structures 110 provide for cathode endpoints 166 for the first sidewall 275 and second sidewall 276 and at the least two sidewalls 271, 272 and at least two more sidewalls 273, 274. The cathode endpoints 166 ensure that the cathode 114 is in contact with the first structure 110A of the overhang structure 110, which is conductive to complete the sub-pixel circuit 100. The cathode endpoints 166 on the sidewalls 271, 272, 273, 274, 275, and 276 protect the PDL structures 126A from contact to etchant in subsequent processes. The overhang structures 110 provide for OLED endpoints 158 for the first sidewall 275 and second sidewall 276 and at the least two sidewalls 271, 272 and at least two more sidewalls 273, 274. In some embodiments, the OLED endpoints 158 have an endpoint along the first sidewall 275, second sidewall 276, at the least two sidewalls 271, 272, and at least two more sidewalls 273, 274 such that the OLED material 112 does not contact the second structure 110B.

FIG. 4A-4E show cross-sectional views of the sub-pixel 106. FIG. 4A is a cross-sectional view of the first sidewall 275 of second sub-pixel circuit 100B at section line A-A. FIG. 4B is a cross-sectional view of the second sidewall 276 of the second sub-pixel circuit 100B at section line B-B. FIG. 4C is a cross-sectional view of the first portion 271 of the at least two sidewalls 271, 272 of the second sub-pixel circuit 100B at section line C-C. FIG. 4D is a cross-sectional view of the second portion 272 of the at least two sidewalls 271, 272 of the second sub-pixel circuit 100B at section line D-D. FIG. 4E is a cross-sectional view of the second portion 272 of the at least two sidewalls 271, 272 of the second sub-pixel circuit 100B at section line E-E. FIG. 4A-4E show the cross-sections after the deposition of the cathode 114, the additional OLED material 112, and the HIL material 150. The first sidewall 275 of the first structure 110A and the second sidewall 276 of the first structure 110A have a cathode thickness t₅. The cathode thickness t₅ is at a midpoint between the cathode endpoint 166 and the OLED endpoint 158 of the first sidewall 275 of the first structure 110A and second sidewall 276 of the first structure 110A. A first cathode volume vi is the total volume of the cathode 114 disposed on the first sidewall 275 and second sidewall 276 from the cathode endpoint 166 to the OLED endpoint 158. The at least two sidewalls 271, 272 of the first structure 110A and at least two more sidewalls 273, 274 of the first structure 110A have a cathode thickness t₅. The cathode thickness to is at a midpoint between the cathode endpoint 166 and the OLED endpoint 158 of the at least two sidewalls 271, 272 and at least two more sidewalls 273, 274. A second cathode volume v₂ is the total volume of the cathode 114 disposed on the at least two sidewalls 271,272 and at least two more sidewalls 273, 274 from the cathode endpoint 166 to the OLED endpoint 158. In one embodiment, the cathode thickness t₅ is greater than the cathode thickness t₆. In one embodiment, the cathode thickness t₆ is about 10% to about 99% of the cathode thickness t₅. In one embodiment, the first cathode volume v₁ of the cathode 114 on the first sidewall 275 and the second sidewall 276 is greater than the second cathode volume v₂ on the at least two sidewalls 271, 272 and the at least two more sidewalls 273, 274. The second cathode volume v₂ on the at least two sidewalls 271, 272 and the at least two more sidewalls 273, 274 is between about 10% and about 99% of the first cathode volume v₁ of the cathode 114 on the first sidewall 275 and the second sidewall 276. The first sidewall 275 and the second sidewall 276 have an OLED thickness t₇. The at least two sidewalls 271,272 and at least two more sidewalls 273, 274 have an OLED thickness t₈. The OLED thicknesses t₇ and t₈ are measured at the OLED endpoint 158.

The overhang structures 110 provide for cathode endpoints 166 for the first sidewall 275 and second sidewall 276 and at the least two sidewalls 271, 272 and at least two more sidewalls 273, 274. The cathode endpoints 166 ensure that the cathode 114 is in contact with the first structure 110A of the overhang structure 110, which is conductive to complete the sub-pixel circuit 100. The cathode endpoints 166 on the sidewalls 271, 272, 273, 274, 275, and 276 protect the PDL structures 126A from contact to etchant in subsequent processes. The overhang structures 110 provide for OLED endpoints 158 for the first sidewall 275 and second sidewall 276 and at the least two sidewalls 271, 272 and at least two more sidewalls 273, 274. In some embodiments, the OLED endpoints 158 have an endpoint along the first sidewall 275, second sidewall 276, at the least two sidewalls 271, 272, and at least two more sidewalls 273, 274 such that the OLED material 112 does not contact the second structure 110B. As shown in FIG. 4E, the angle of the at least two sidewalls 271, 272 and angle of the at least two more sidewalls 273, 274 further define an OLED endpoint 158 and a cathode endpoint 166. The overhang structures 110 and the angle of the at least two sidewalls 271, 272 and of the at least two more sidewalls 273, 274 provide for a shadowing effect during deposition at an angle.

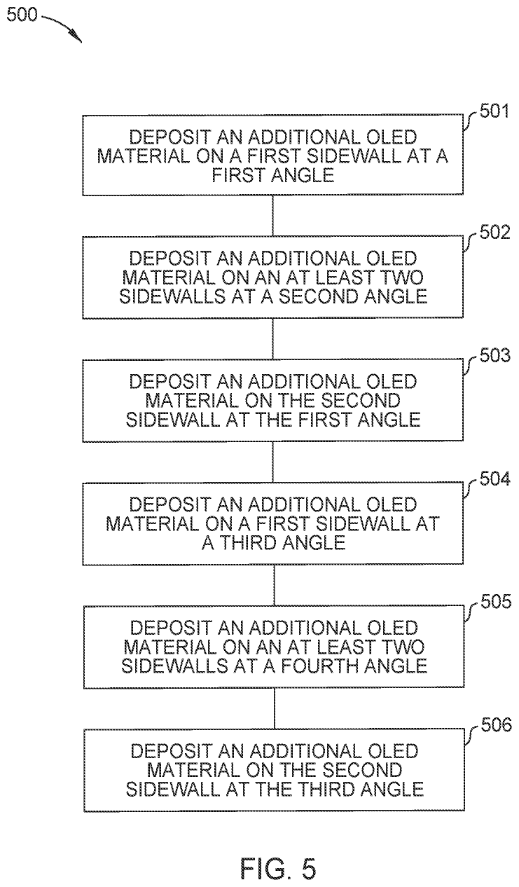

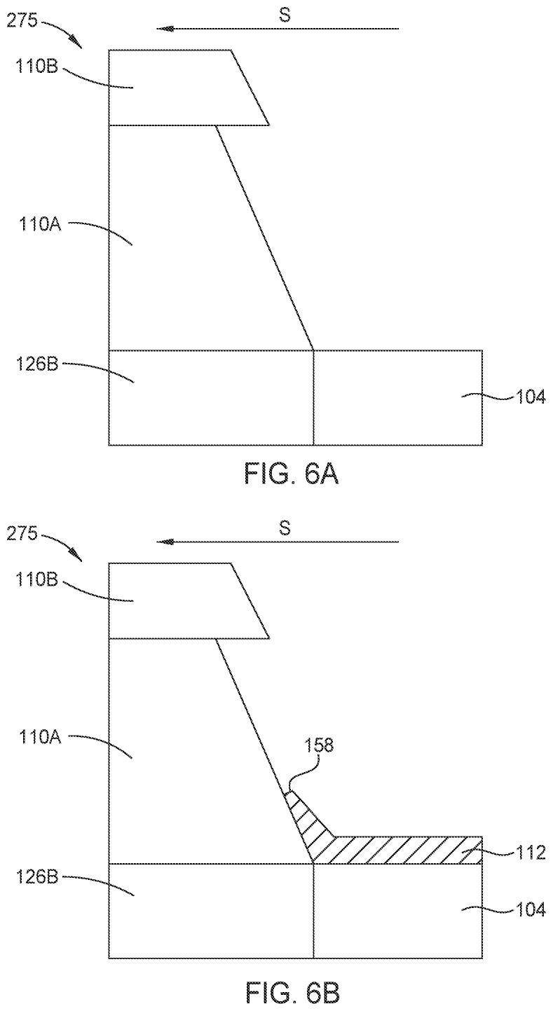

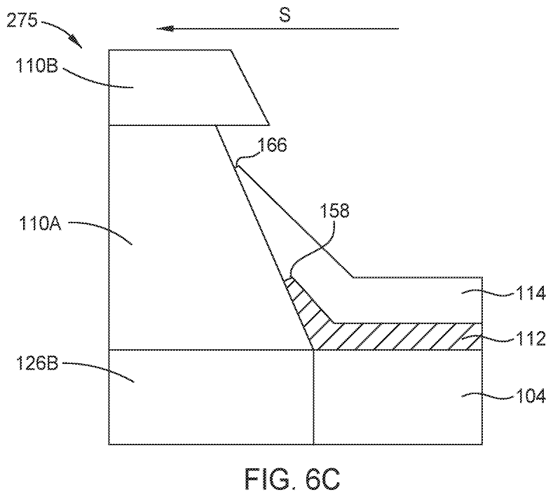

FIG. 5 illustrates a method 500 of forming a sub-pixel circuit 100. FIGS. 6A-6C are schematic, cross-sectional views of a substrate 102 during the method 500 for forming the sub-pixel circuit 100. In operation 501, as shown in FIGS. 6A and 6B, the additional OLED material 112 is deposited on a first sidewall 275 at a first angle. In one embodiment, the deposition is evaporation deposition. In one embodiment, the deposition of the additional OLED material 112 occurs as the substrate 102 proceeds in the scan direction S. In another embodiment, the deposition of the additional OLED material 112 occurs as the deposition source proceeds in the scan direction S. The deposition source includes a plurality of nozzles that extend along a nozzle direction N. As the nozzle moves along the scan direction S, the overhang structures 110 ensure that the height of the OLED endpoints 158 on the first sidewall 275 does not contact the second structure 110B. The shadowing of the overhang extension 109 of the second structure provides for evaporation deposition of the additional OLED material 112 at an angle set by the evaporation source. I.e., the overhang structures 110 provide for a shadowing effect during evaporation deposition with the evaporation angle set by the evaporation source configured to emit the OLED material at a particular angle with regard to the overhang structure 110. The first sidewall 275 is perpendicular to (e.g., normal to) the scan direction S,

At operation 502, the additional OLED material 112 is deposited on an at least two sidewalls 271, 272 at a second angle. In some embodiments, the additional OLED material 112 is deposited on the at least two more sidewalls 273, 274. The at least two or more sidewalls 273, 274 are at an angle of about 5 degrees to about 85 degrees from the first sidewall 275 and the second sidewall 276. The angle of the at least two or more sidewalls 273, 274 with regard to the first sidewall 275 and second sidewall 276 affect the evaporation angle as the nozzles move along the scan direction S. As the nozzle moves along the scan direction S, the overhang structures 110 ensure that the height of the OLED endpoints 158 on the at least two sidewalls 271, 272 does not contact the second structure 110B.

At operation 503, the additional OLED material 112 is deposited on a second sidewall 276 at the first angle. As the nozzle moves along the scan direction S. the overhang structures 110 ensure that the height of the OLED endpoints 158 on the second sidewall 276 does not contact the second structure 110B. The second sidewall 276 is perpendicular to (e.g., normal to) the scan direction S,

At operation 504, the cathode 114 is deposited on the first sidewall 275 at a third angle. In one embodiment, the deposition is evaporation deposition. The shadowing of the overhang extension 109 of the second structure provides for evaporation deposition of the cathode 114 at an angle set by the evaporation source. I.e., the overhang structures 110 provide for a shadowing effect during evaporation deposition with the evaporation angle set by the evaporation source configured to emit the cathode 114 at a particular angle with regard to the overhang structure 110.

At operation 505, the cathode is deposited on the on an at least two sidewalls 271, 272 at a second angle. In some embodiments, the cathode 114 is deposited on the at least two more sidewalls 273, 274. The at least two or more sidewalls 273, 274 are at an angle of about 5 degrees to about 85 degrees from the first sidewall 275 and the second sidewall 276. The angle of the at least two or more sidewalls 273, 274 with regard to the first sidewall 275 and second sidewall 276 affect the evaporation angle as the nozzles move along the scan direction S.

At operation 506, the cathode 114 is deposited on a second sidewall 276 at the third angle.

In the embodiments of FIG. 3A-3D, the cathode 114 is deposited, as shown in FIGS. 3A and 3B, such that the cathode thickness of the first sidewall 275 and the second sidewall 276 are a thickness t₁. The cathode 114 is deposited, as shown in FIG. 3C, such that the cathode thickness on the first portion 271 of the at least two sidewalls 271, 272 and the third portion 273 of the at least two more sidewalls 273, 274 are a thickness t₂. The cathode thickness t₁ of the first sidewall 275 and the second sidewall 276 are greater than the cathode thickness t₂ on the first portion 271 and the third portion 274. The cathode 114 is deposited, as shown in FIG. 3D, such that the cathode thickness on the second portion 272 of the at least two sidewalls 271, 272 and the fourth portion 274 of the at least two more sidewalls 273, 274 are a thickness t₂. The cathode thickness t₁ of the first sidewall 275 and the second sidewall 276 are greater than the cathode thickness t₂ on the second portion 272 and the fourth portion 274. In one embodiment, the ratio of the thickness t₁ of first sidewall 275 and the second sidewall 276 to the thickness t₂ of the at least two sidewalls 271, 272 and at least two more sidewalls 273, 274 is between about 1:1 and about 10:1.

In the embodiments of FIG. 4A-4D, the cathode 114 is deposited, as shown in FIGS. 4A and 4B, such that the cathode thickness of the first sidewall 275 is a thickness t₅. The cathode 114 is deposited, as shown in FIG. 3C, such that the cathode thickness on the first portion 271 of the at least two sidewalls 271, 272 and the third portion 273 of the at least two more sidewalls 273, 274 are a thickness t₆. The cathode thickness t₅ of the first sidewall 275 and the second sidewall 276 are greater than the cathode thickness t₆ on the first portion 271 and the third portion 274. The cathode 114 is deposited, as shown in FIG. 3D, such that the cathode thickness on the second portion 272 of the at least two sidewalls 271, 272 and the fourth portion 274 of the at least two more sidewalls 273, 274 are a thickness t₆. The cathode thickness t₅ of the first sidewall 275 and the second sidewall 276 are greater than the cathode thickness t₆ on the second portion 272 and the fourth portion 274. In one embodiment, the ratio of the thickness t₅ of first sidewall 275 and the second sidewall 276 to the thickness t₆ of the at least two sidewalls 271, 272 and at least two more sidewalls 273, 274 is between about 1:1 and about 10:1.

In one embodiment, the deposition of the cathode 114 occurs as the substrate 102 proceeds in the scan direction S. In another embodiment, the deposition of the cathode 114 occurs as the deposition source proceeds in the scan direction S. The cathode thicknesses result from the configuration of the deposition angle and the overhang 109. The deposition source includes a plurality of nozzles that extend along a nozzle direction N. As the nozzle moves along the scan directions, the overhang structures 110 ensure that the cathode 114 on the first sidewall 275, the second sidewall 276, the at least two sidewalls 271, 272, and at least two more sidewalls 273, 274 contacts the first structure 110A to complete the sub-pixel circuit 100. The cathode 114 protects the PDL structures 126A from contact to etchant in subsequent processes. In one embodiment, the overhang structure 110 ensures that the cathode endpoints 166 on the first sidewall 275, the second sidewall 276, the at least two sidewalls 271, 272, and at least two more sidewalls 273, 274 contact the overhang 109 to form a circuit between the metal-containing layer 104, the OLED material 112, and the cathode.

In summation, each of the embodiments described herein of the sub-pixel circuit include a plurality of sub-pixels with each of the sub-pixels defined by adjacent overhang structures that are permanent to the sub-pixel circuit. The overhangs define a cathode thickness for a first sidewall, a second sidewall, and at least two sidewall connecting the first sidewall and the second sidewall. The cathode thickness of the first sidewall and the second sidewall are greater than the cathode thickness on the at least two sidewalls.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
overhang structures disposed over the substrate, each overhang structure having an second structure disposed over a first structure, the second structure having an overhang extension extending laterally past the first structure, the first structure comprising:
a first sidewall opposing a second sidewall, the first sidewall and the second sidewall connected to each other; and
a plurality of sub-pixels, each sub-pixel comprising:
an organic light-emitting diode (OLED) material; and
a cathode disposed over the OLED material and extending under the overhang extension such that the cathode contacts the first sidewall and the second sidewall of the first structure under the overhang extension.

2. The device of claim 1, further comprising:
at least two sidewalls connecting a first end of the first sidewall to the first end of the second sidewall; and
at least two more sidewalls connecting a second end of the first sidewall to the second end of the second sidewall.

3. The device of claim 2, wherein a cathode thickness at a midpoint between a cathode endpoint and an OLED endpoint on the first sidewall and the second sidewall is greater than the cathode thickness on the at least two sidewalls.

4. The device of claim 3, wherein a ratio of a thickness of a cathode thickness on the first sidewall and the second sidewall to the thickness of the cathode thickness on the at least two sidewalls is between 1:1 and 10:1.

5. The device of claim 1, wherein the plurality of sub-pixels are hexagonal sub-pixels.

6. The device of claim 1, wherein each sub-pixel further comprises a via hole disposed through the sub-pixel.

7. The device of claim 1, further comprising pixel-defining layer (PDL) structures disposed on the substrate, and wherein the overhang structures are disposed over the PDL structures.

8. The device of claim 7, wherein the PDL structures comprise polyimides, silicon oxide (SiO₂), silicon nitride (Si₃N₄), silicon oxynitride (Si₂N₂O), magnesium fluoride (MgF₂), or combinations thereof.

9. The device of claim 1, further comprising a pixel isolation structure (PIS) disposed on the substrate, and wherein the overhang structures are disposed over the PIS.

10. The device of claim 9, wherein the PIS comprises polyimides, silicon oxide (SiO₂), silicon nitride (Si₃N₄), silicon oxynitride (Si₂N₂O), magnesium fluoride (MgF₂), or combinations thereof.

11. A device, comprising:
a substrate;
overhang structures disposed over the substrate, each overhang structure having an second structure disposed over a first structure, the second structure having an overhang extension extending laterally past the first structure, the first structure comprising:
a first sidewall opposing a second sidewall and at least four angled sidewalls, wherein at least two of the four angled sidewalls connecting a first end of the first sidewall to the first end of the second sidewall and at least two more of the four angled sidewalls connecting a second end of the first sidewall and a second end of the second sidewall; and
a plurality of sub-pixels, each sub-pixel comprising:
an organic light-emitting diode (OLED) material; and
a cathode disposed over the OLED material and extending under the overhang extension such that the cathode contacts the first sidewall, the second sidewall, and the at least four angled sidewalls of the first structure under the overhang extension, wherein a cathode thickness at a midpoint between a cathode endpoint and an OLED endpoint on the first sidewall and the second sidewall is greater than the cathode thickness on the at least four angled sidewalls.

12. The device of claim 11, further comprising pixel-defining layer (PDL) structures disposed on the substrate, and wherein the overhang structures are disposed over the PDL structures.

13. The device of claim 11, wherein the plurality of sub-pixels are hexagonal sub-pixels, wherein the first sidewall and the second sidewall are normal to a scan direction.

14. The device of claim 11, further comprising a pixel isolation structure (PIS) disposed on the substrate, and wherein the overhang structures are disposed over the PIS.

15. The device of claim 11, wherein:
a ratio of a thickness of a cathode thickness on the first sidewall and the second sidewall to the thickness of the cathode thickness on the at least four angled sidewalls is between 1:1 and 10:1.

16. A method of forming a device, comprising:
depositing an OLED material at a first angle, wherein:
overhangs are disposed over a substrate, each overhang structure having an second structure disposed over a first structure, the second structure having an overhang extension extending laterally past the first structure, the first structure comprising:
a first sidewall opposing a second sidewall and at least two sidewalls connecting a first end of the first sidewall to a first end of the second sidewall; and
at least two more sidewalls connecting a second end of the first sidewall to the second end of the second sidewall; and
depositing a cathode at a second angle such that the cathode contacts the first sidewall, the second sidewall, the at least two sidewalls, and the at least two more sidewalls of the first structure under the overhang extension.

17. The method of claim 16, wherein the OLED material and the cathode are deposited as the substrate or a deposition source moves in a scan direction.

18. The method of claim 16, wherein:
a cathode thickness at a midpoint between a cathode endpoint and an OLED endpoint on the first sidewall and the second sidewall is greater than the cathode thickness on the at least two sidewalls.

19. The method of claim 16, wherein:
a ratio of a thickness of a cathode thickness on the first sidewall and the second sidewall to the thickness of the cathode thickness on the at least two sidewalls is between 1:1 and 10:1.

20. The method of claim 16, wherein each sub-pixel further comprises:
an anode; and
a via hole disposed through the anode.
